(19) United States
(12) Patent Application Publication
(10) Pub. No.: US 2026/0255561 A1
(43) Pub. Date: Aug. 27, 2026

(54) ELECTROMAGNETIC FIELD SHIELDING DEVICE FOR ELECTRICAL FIXTURES

(71) Applicant: Evan Blazso Rock, Papaikou, HI (US)

(72) Inventor: Evan Blazso Rock, Papaikou, HI (US)

(21) Appl. No.: 19/650,418

(22) Filed: Apr. 17, 2026

Related U.S. Application Data
(63) Continuation of application No. 18/885,580, filed on Sep. 14, 2024, now Pat. No. 12,604,445.

(51) Int. Cl. H05K 9/00; H01R 13/443; H02G 3/14

(52) U.S. Cl. CPC H05K 9/0018; H01R 13/443; H02G 3/14

(57) ABSTRACT

An electromagnetic field (EMF) shielding device for electrical fixtures is disclosed. The device includes a cover body configured to enclose at least a portion of an electrical fixture, a conductive barrier element positioned between the electrical fixture and the external environment, and a mounting structure configured to mechanically engage the electrical fixture. The barrier element includes a prong configured for insertion into a ground terminal of the electrical fixture to establish a grounding path. The mounting structure includes support members configured for insertion into corresponding openings of the electrical fixture to retain the device in position. The device operates passively without requiring an external power source and is configured to attenuate electromagnetic field (EMF) emissions through conductive shielding and grounding.

### FIELD OF INVENTION

The present disclosure relates generally to an insulation accessory of electrical fixtures, and more particularly to a simple, cost-effective, and efficient electromagnetic field (EMF) shielding device configured for use with electrical fixtures to attenuate electromagnetic emissions. The EMF shielding device further pertains to a grounding-assisted shielding arrangement integrated with the cover structure for reducing exposure to electromagnetic fields generated by electrical outlets, switches, and similar electrical installations.

### BACKGROUND

Electrical fixtures, including wall outlets, switches, receptacles, and similar power distribution interfaces, are extensively deployed in residential, commercial, and industrial environments for supplying electrical energy to a wide range of devices. During normal operation, such electrical fixtures inherently generate electromagnetic fields (EMFs) as a consequence of alternating current flow, voltage differentials, and associated electromagnetic coupling phenomena. These EMFs may propagate outward from the fixture into the surrounding environment and contribute to cumulative electromagnetic exposure in occupied spaces.

A variety of techniques have been developed to mitigate electromagnetic interference and reduce field propagation. Conventional approaches include the use of shielded wiring, grounded conduits, ferrite-based suppression components, and filtering circuits integrated within powered electronic devices. While such approaches can reduce electromagnetic field (EMF) emissions to some extent, they often require modification of building infrastructure, incorporation of additional components within electrical systems, or reliance on powered or active circuitry, thereby increasing installation complexity and cost.

To address localized emission at the point of use, shielding solutions associated directly with electrical fixtures have also been proposed. For instance, U.S. Pat. No. 6,184,477 discloses an electrical outlet cover incorporating conductive shielding elements positioned relative to the outlet structure. Such arrangements are directed toward attenuating electromagnetic field (EMF) emissions emanating from the outlet interface. However, such devices are generally configured as shielding layers or plates and may not include a dedicated grounding member configured for direct insertion into a ground terminal of the electrical fixture, which can influence the effectiveness and consistency of electromagnetic attenuation.

In another approach, U.S. Patent Application Publication No. 2014/0264722 describes a plug-in electromagnetic interference shielding device that includes shielding and filtering components integrated within a module adapted to be inserted into an electrical outlet. Such devices may utilize internal circuitry, filtering elements, or passive components to reduce interference. However, plug-in configurations of this type may not provide structural integration with the fixture itself, may not ensure coverage of all emission regions associated with the fixture face, and may not be configured to function as a permanent or semi-permanent cover structure.

More broadly, existing solutions directed to EMF reduction at electrical fixtures may exhibit one or more limitations, including incomplete coverage of emission zones, absence of direct and reliable grounding engagement with the fixture, dependence on active or semi-active components, or insufficient mechanical retention relative to the electrical fixture. Additionally, many existing devices are not configured to simultaneously provide a cover structure, grounding-based shielding, and stable mechanical engagement using existing openings of the fixture.

Accordingly, there remains a need for an improved electromagnetic field shielding device that is configured for placement at the electrical fixture interface, provides effective attenuation of electromagnetic field (EMF) emissions through a grounded shielding arrangement, ensures reliable mechanical retention relative to the fixture, and operates passively without requiring an external power source, while being compatible with standard electrical outlet and switch configurations.

### SUMMARY OF THE INVENTION

The following presents a simplified summary of one or more embodiments of the present disclosure to provide a basic understanding of such embodiments. This summary is not an extensive overview of all contemplated embodiments and is intended to neither identify key nor critical elements of all embodiments, nor delineate the scope of any or all embodiments.

The present disclosure, in one or more embodiments, relates to a simple, cost-effective, and efficient electromagnetic field (EMF) shielding device configured for use with electrical fixtures to attenuate electromagnetic field (EMF) emissions.

According to an aspect, the invention provides an electromagnetic field (EMF) shielding device for electrical fixtures. In one embodiment herein, the EMF shielding device comprises a cover body, a barrier element, and a mounting structure.

In one embodiment herein, the cover body is adapted to enclose at least a portion of an electrical fixture. The cover body is configured as at least one of a faceplate, a plug-in module, an insert, or an adapter. The cover body comprises an electrically insulating material selected from the group consisting of plastic, rubber, ceramic, silicone, fiberglass, epoxy resin, and polytetrafluoroethylene (PTFE).

In one embodiment herein, the barrier element is coupled to a rear side of the cover body. The barrier element is configured to be positioned between the electrical fixture and the external environment. The barrier element is dimensioned to substantially cover a front-facing surface of the electrical fixture. The barrier element comprises a prong extending from a rear portion thereof. The prong is configured for insertion into a ground terminal of the electrical fixture.

In one embodiment herein, the prong extends through an aperture formed in the mounting structure and protrudes rearwardly for insertion into the ground terminal of the electrical fixture. The barrier element comprises a conductive metal selected from the group consisting of copper, aluminum, and brass. The prong is configured to facilitate reduction of electromagnetic field emissions from the electrical fixture. The prong comprises a conductive material to enable electrical conductivity. In one embodiment herein, the conductive material comprises at least one of copper, aluminum, brass, steel, silver, conductive alloys, or conductive composites.

In one embodiment herein, the mounting structure is coupled to a rear side of the barrier element. The mounting structure is configured to mechanically engage the electrical fixture to retain the cover body in position relative to the electrical fixture. The mounting structure comprises a pair of support members extending from a rear portion thereof. The pair of support members is configured to be inserted into corresponding openings of the electrical fixture.

In one embodiment herein, the mounting structure comprises an electrically insulating material selected from the group consisting of plastic, rubber, ceramic, silicone, fiberglass, epoxy resin, and polytetrafluoroethylene (PTFE). In one embodiment herein, the EMF shielding device is configured to operate without connection to an external power source. The EMF shielding device further comprises one or more fastening or conductive elements selected from the group consisting of screws, clips, and contact pads.

While multiple embodiments are disclosed, still other embodiments of the present disclosure will become apparent to those skilled in the art from the following detailed description, which shows and describes illustrative embodiments of the invention. As will be realized, the various embodiments of the present disclosure are capable of modifications in various obvious aspects, all without departing from the spirit and scope of the present disclosure. Accordingly, the drawings and detailed description are to be regarded as illustrative in nature and not restrictive.

### BRIEF DESCRIPTION OF THE DRAWINGS

The accompanying drawings, which are incorporated in and constitute a part of the specification, illustrate an embodiment of the invention, and, together with the description, explain the principles of the invention.

FIG. 1 illustrates an isometric view of an electromagnetic field (EMF) shielding device, in accordance with embodiments of the invention.

FIG. 2 illustrates exploded front view of the EMF shielding device, in accordance with embodiments of the invention.

FIG. 3 illustrates exploded side views of the EMF shielding device, in accordance with embodiments of the invention.

### DETAILED DESCRIPTION

Reference will now be made in detail to the present preferred embodiments of the invention, examples of which are illustrated in the accompanying drawings. Wherever possible, the same reference numerals are used in the drawings and the description to refer to the same or like parts.

Electrical fixtures such as outlets, switches, and receptacles generate electromagnetic fields (EMFs) during operation due to alternating current flow and associated electromagnetic interactions. These EMFs may propagate into surrounding areas and contribute to localized electromagnetic exposure. Existing approaches for reducing electromagnetic field (EMF) emissions typically involve shielding at the wiring level, use of specialized cables, or incorporation of filtering circuits. Such approaches may require modification of existing infrastructure, increased installation complexity, or reliance on powered components. In addition, certain fixture-level shielding solutions may not provide consistent grounding engagement, complete coverage of emission regions, or secure mechanical integration with standard electrical fixtures.

Accordingly, a need exists for an electromagnetic field (EMF) shielding device 100 that provides effective electromagnetic field attenuation at the point of use while being compatible with existing electrical fixtures, mechanically stable, and operable without external power. The electromagnetic field (EMF) shielding device 100 facilitates passive attenuation of electromagnetic fields without requiring external power or modification of existing infrastructure.

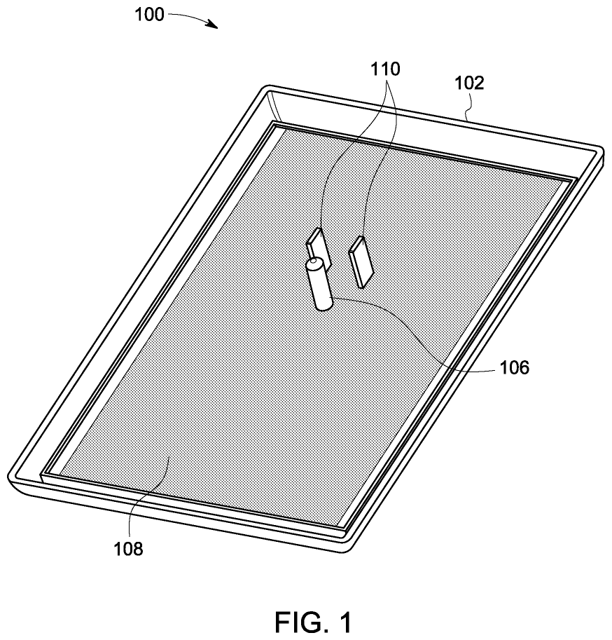

FIG. 1 illustrates an isometric view of an electromagnetic field (EMF) shielding device 100. The EMF shielding device 100 is configured for use with electrical fixtures. The EMF shielding device 100 is structured to attenuate electromagnetic field (EMF) emissions generated during operation of the electrical fixture through a passive shielding and grounding arrangement. In one embodiment, the EMF shielding device 100 comprises a cover body 102, a barrier element 104, and a mounting structure 108 arranged in a layered configuration. The arrangement is configured such that the barrier element 104 is positioned between the electrical fixture and the external environment, while the cover body 102 provides an outward-facing interface.

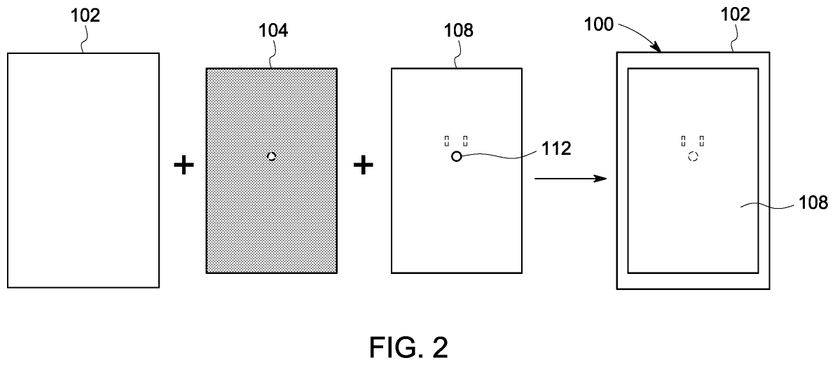

FIG. 2 illustrates exploded front view of the EMF shielding device 100. In one embodiment, the cover body 102 is configured to enclose at least a portion of the electrical fixture and to provide a protective and insulating interface. The cover body 102 is configured as at least one of a faceplate, a plug-in module, an insert, or an adapter, thereby enabling compatibility with different types of electrical fixtures including outlets, switches, and receptacles.

The cover body 102 comprises an electrically insulating material selected from the group consisting of plastic, rubber, ceramic, silicone, fiberglass, epoxy resin, and polytetrafluoroethylene (PTFE). The insulating nature of the cover body 102 reduces the likelihood of unintended electrical contact while allowing integration with existing fixtures. In alternative embodiments, the cover body 102 may include apertures, slots, or openings aligned with functional portions of the electrical fixture, including socket openings, switch toggles, or control interfaces.

In one embodiment, the barrier element 104 is coupled to a rear side of the cover body 102 and is configured to be positioned between the electrical fixture and the external environment. The barrier element 104 is dimensioned to substantially cover a front-facing surface of the electrical fixture to provide a shielding interface. The barrier element 104 comprises a conductive material selected from the group consisting of copper, aluminum, and brass. The conductive nature of the barrier element 104 facilitates attenuation of electromagnetic fields by redistributing and reducing field propagation. In some embodiments, the barrier element 104 is formed as a continuous sheet. In other embodiments, the barrier element 104 may include patterned regions, perforations, or layered conductive structures to balance shielding effectiveness and structural requirements.

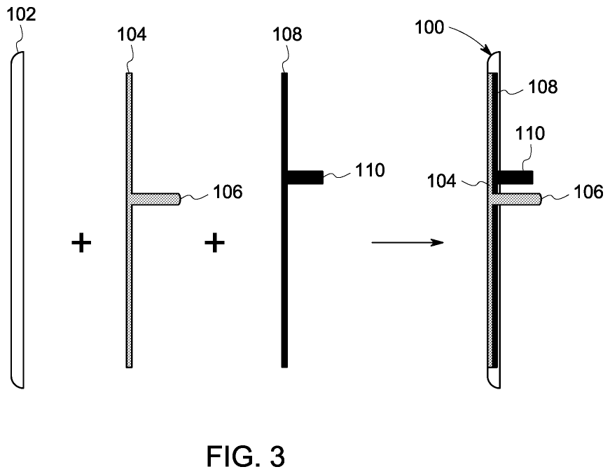

FIG. 3 illustrates exploded side views of the EMF shielding device 100. In one embodiment, the barrier element 104 comprises a prong 106 extending from a rear portion thereof. The prong 106 is configured for insertion into a ground terminal of the electrical fixture to establish an electrical grounding path. The prong 106 extends through an aperture 112 formed in the mounting structure 108 and protrudes rearwardly to engage the ground terminal. The grounding connection enables dissipation or redirection of electromagnetic energy through a grounded conductive path, thereby improving shielding performance.

In one embodiment, the prong 106 is adapted to influence electromagnetic field distribution and enhance attenuation characteristics. In alternative embodiments, the prong 106 may comprise a straight, forked, curved, or multi-contact configuration depending on the grounding interface of the electrical fixture. The prong 106 comprises a conductive material to ensure effective electrical conductivity. In some embodiments, the conductive material may include, but is not limited to, metals such as copper, aluminum, brass, steel, silver, conductive alloys, or conductive composites, and thereof. For example, the conductive grounding prong 106 is configured to establish an electrical grounding path. The prong 106 may comprise a solid, cylindrical, flat, or other grounding-compatible configuration depending on an electrical interface.

In one embodiment, the mounting structure 108 is coupled to a rear side of the barrier element 104 and is configured to mechanically engage the electrical fixture to retain the cover body 102 in position relative to the electrical fixture. The mounting structure 108 comprises a pair of support members 110 extending from a rear portion thereof. The pair of support members 110 is configured for insertion into corresponding openings of the electrical fixture to provide positional stability and resistance to displacement. The mounting structure 108 comprises an electrically insulating material selected from the group consisting of plastic, rubber, ceramic, silicone, fiberglass, epoxy resin, and polytetrafluoroethylene (PTFE), thereby maintaining electrical isolation while providing structural support.

In alternative embodiments, the mounting structure 108 may include snap-fit features, threaded elements, clips, friction-fit members, or expandable members configured to engage different types of electrical fixtures. In one embodiment, the EMF shielding device 100 further comprises one or more fastening or conductive elements selected from the group consisting of screws, clips, and contact pads. These elements are configured to facilitate assembly, enhance mechanical retention, and optionally improve electrical continuity between components. In operation, the EMF shielding device 100 is positioned over or integrated with the electrical fixture such that the barrier element 104 is disposed between the fixture and the external environment. The prong 106 is inserted into the ground terminal, establishing a grounding path.

The conductive barrier element 104 interacts with electromagnetic fields generated by the electrical fixture, reducing field propagation through shielding and redistribution of electromagnetic energy. The grounding connection provided by the prong 106 facilitates dissipation of electromagnetic energy, thereby enhancing attenuation. The cover body 102 provides insulation and physical protection, while the mounting structure 108 maintains alignment and secure engagement with the electrical fixture. The EMF shielding device 100 operates passively without requiring connection to an external power source.

In one embodiment, the EMF shielding device 100 is installed by aligning the mounting structure 108 with corresponding openings of the electrical fixture and inserting the support members into the openings. The prong 106 is aligned with and inserted into the ground terminal of the fixture. The EMF shielding device 100 is then secured in place through engagement of the mounting structure 108 and optional fastening elements. Once installed, the EMF shielding device 100 remains in position during normal operation of the electrical fixture. The EMF shielding device 100 may be configured for removable installation or semi-permanent attachment depending on the mounting configuration.

In various embodiments, the barrier element 104 may extend beyond the perimeter of the electrical fixture to provide enhanced shielding coverage. The EMF shielding device 100 may be configured without the grounding prong 106 and instead rely on capacitive or proximity-based shielding. The cover body 102 and barrier element 104 may be integrally formed or modularly assembled. Multiple prongs 106 or grounding contacts may be provided for different grounding configurations. The EMF shielding device 100 may be adapted for use with multi-socket outlets, industrial panels, or specialized electrical interfaces. In one embodiment herein, the EMF shielding device 100 provides passive operation without external power, grounding-assisted electromagnetic attenuation, compatibility with existing electrical fixtures, secure mechanical engagement, and scalable and adaptable configurations.

In the foregoing description various embodiments of the present disclosure have been presented for the purpose of illustration and description. They are not intended to be exhaustive or to limit the invention to the precise form disclosed. Obvious modifications or variations are possible in light of the above teachings. The various embodiments were chosen and described to provide the best illustration of the principles of the disclosure and their practical application, and to enable one of ordinary skill in the art to utilize the various embodiments with various modifications as are suited to the particular use contemplated. All such modifications and variations are within the scope of the present disclosure as determined by the appended claims when interpreted in accordance with the breadth they are fairly, legally, and equitably entitled.

It will readily be apparent that numerous modifications and alterations can be made to the processes described in the foregoing examples without departing from the principles underlying the invention, and all such modifications and alterations are intended to be embraced by this application.

The claimed invention is:

1. An electromagnetic field (EMF) shielding device, comprising:
a cover body adapted to enclose at least a portion of an electrical fixture;
a barrier element coupled to a rear side of the cover body, wherein the barrier element is configured to be positioned between the electrical fixture and the external environment,
wherein the barrier element comprises a prong extending from a rear portion thereof, wherein the prong is configured for insertion into a ground terminal of the electrical fixture; and
a mounting structure coupled to a rear side of the barrier element, wherein the mounting structure is configured to mechanically engage the electrical fixture to retain the cover body in position relative to the electrical fixture,
wherein the mounting structure comprises a pair of support members extending from a rear portion thereof, wherein the pair of support members is configured to be inserted into corresponding openings of the electrical fixture.

2. The EMF shielding device of claim 1, wherein the prong extends through an aperture formed in the mounting structure and protrudes rearwardly for insertion into the ground terminal of the electrical fixture.

3. The EMF shielding device of claim 1, wherein the EMF shielding device is configured to operate without connection to an external power source.

4. The EMF shielding device of claim 1, wherein the barrier element is dimensioned to substantially cover a front-facing surface of the electrical fixture.

5. The EMF shielding device of claim 1, wherein the cover body is configured as at least one of a faceplate, a plug-in module, an insert, or an adapter.

6. The EMF shielding device of claim 1, wherein the barrier element comprises a conductive metal selected from the group consisting of copper, aluminum, and brass.

7. The EMF shielding device of claim 1, wherein the mounting structure comprises an electrically insulating material selected from the group consisting of plastic, rubber, ceramic, silicone, fiberglass, epoxy resin, and polytetrafluoroethylene (PTFE).

8. The EMF shielding device of claim 1, wherein the cover body comprises an electrically insulating material selected from the group consisting of plastic, rubber, ceramic, silicone, fiberglass, epoxy resin, and polytetrafluoroethylene (PTFE).

9. The EMF shielding device of claim 1, wherein the prong is configured to facilitate reduction of electromagnetic field emissions from the electrical fixture.

10. The EMF shielding device of claim 1, wherein the prong comprises a conductive material, wherein the conductive material comprises at least one of copper, aluminum, brass, steel, silver, conductive alloys, or conductive composites.

11. The EMF shielding device of claim 1, wherein the EMF shielding device further comprises one or more fastening or conductive elements selected from the group consisting of screws, clips, and contact pads.

12. An electromagnetic field (EMF) shielding device, comprising:
a cover body adapted to enclose at least a portion of an electrical fixture;
a barrier element coupled to a rear side of the cover body, wherein the barrier element is configured to be positioned between the electrical fixture and the external environment,
wherein the barrier element comprises a prong extending from a rear portion thereof, wherein the prong is configured for insertion into a ground terminal of the electrical fixture,
wherein the prong is configured to facilitate reduction of electromagnetic field emissions from the electrical fixture; and
a mounting structure coupled to a rear side of the barrier element, wherein the mounting structure is configured to mechanically engage the electrical fixture to retain the cover body in position relative to the electrical fixture,
wherein the mounting structure comprises a pair of support members extending from a rear portion thereof, wherein the pair of support members is configured to be inserted into corresponding openings of the electrical fixture.

13. The EMF shielding device of claim 12, wherein the prong extends through an aperture formed in the mounting structure and protrudes rearwardly for insertion into the ground terminal of the electrical fixture.

14. The EMF shielding device of claim 12, wherein the barrier element comprises a conductive metal selected from the group consisting of copper, aluminum, and brass.

15. The EMF shielding device of claim 12, wherein the mounting structure comprises an electrically insulating material selected from the group consisting of plastic, rubber, ceramic, silicone, fiberglass, epoxy resin, and polytetrafluoroethylene (PTFE).

16. The EMF shielding device of claim 12, wherein the cover body comprises an electrically insulating material selected from the group consisting of plastic, rubber, ceramic, silicone, fiberglass, epoxy resin, and polytetrafluoroethylene (PTFE).
